(19) United States
(12) Patent Application Publication
(10) Pub. No.: US 2015/0282315 A1
(43) Pub. Date: Oct. 1, 2015

(54) PRINTED CIRCUIT BOARD AND METHOD OF MANUFACTURING THE SAME

(71) Applicant: SAMSUNG ELECTRO-MECHANICS CO., LTD., Suwon (KR)

(72) Inventors: Jong Gyu CHOI, Sejong (KR); Young Gon KIM, Yeongi (KR); Hyeok HEO, Daejeon (KR)

(73) Assignee: SAMSUNG ELECTRO-MECHANICS CO., LTD., Suwon (KR)

(21) Appl. No.: 14/339,618

(22) Filed: Jul. 24, 2014

(30) Foreign Application Priority Data
Mar. 26, 2014 (KR) 10-2014-0035338

(51) Int. Cl. H05K 1/11; H05K 3/06; H05K 1/09; H05K 3/24

(52) U.S. Cl. CPC H05K 1/111; H05K 3/243; H05K 3/06; H05K 1/09

(57) ABSTRACT

The present invention relates to a printed circuit board, which includes: a connection pad consisting of a seed layer formed on an upper surface of an insulating layer and a metal layer formed on an upper surface of the seed layer; a first plating layer formed to surround the connection pad; and a second plating layer formed on an upper surface of the first plating layer except a side surface of the first plating layer, and a method for manufacturing the same.

### CROSS-REFERENCE TO RELATED APPLICATIONS

Claim and incorporate by reference domestic priority application and foreign priority application as follows:

This application claims the benefit under 35 U.S.C. Section 119 of Korean Patent Application Serial No. 10-2014-0035338, entitled filed Mar. 26, 2014, which is hereby incorporated by reference in its entirety into this application.

### BACKGROUND OF THE INVENTION

1. Field of the Invention

The present invention relates to a printed circuit board and a method of manufacturing the same, and more particularly, to a printed circuit board, which can miniaturize a wire bonding pad, and a method of manufacturing the same.

2. Description of the Related Art

In general, a printed circuit board (PCB) is used in industrial/consumer electronic devices etc. The PCB, which is manufactured by forming a circuit pattern including a connection pad on an upper surface or both surfaces of a board made of a phenol resin or an epoxy resin to mount various kinds of components, is electrically connected to electronic components such as semiconductor chips to supply power to the electronic components and mechanically fix the electronic components at the same time.

Typically, the electronic component or external device connected to the PCB is electrically connected to the connection pad formed on the PCB by wire bonding.

In recent times, since formation of multilayer circuit patterns, miniaturization of circuit patterns, miniaturization, and packaging of the PCB are in progress with the trend of miniaturization, thinning, densification, and packaging, and personal carrying of electronic products, there is also a need for the densification and thinning of the PCB on which the electronic component is mounted, and the PCB is being developed from a single-sided PCB to a multilayer PCB.

In particular, according to the trend of thinning and densification of the PCB, the connection pad included in the PCB is also becoming smaller.

In the prior art, most of the connection pads formed on the PCBs are made of a copper material, and a different kind of material is plated on the outer surface of the connection pad to secure the reliability of wire bonding when the connection pad is connected to the electronic component through wire bonding. However, it is contrary to the trend of miniaturization, and there are constraints on high density circuit design.

### RELATED ART DOCUMENT

### Patent Document

Patent Document 1: Korean Patent Publication No. 2003-0095688

Patent Document 2: Korean Patent Publication No. 2009-0116514

### SUMMARY OF THE INVENTION

The present invention has been invented in order to overcome the above-described problems and it is, therefore, an object of the present invention to provide a printed circuit board, which can achieve densification and miniaturization by forming a connection pad minutely while securing reliability when performing wire bonding of an electronic component and the connection pad using a wire, and a method of manufacturing the same.

Further, it is another object of the present invention to provide a printed circuit board, which can prevent degradation of reliability due to excessive etching of a connection pad, and a method of manufacturing the same.

In addition, it is another object of the present invention to provide a printed circuit board, which can prevent failures such as contact failure of a wire and damage to a connection pad by absorbing shock during wire bonding, and a method of manufacturing the same.

In accordance with one aspect of the present invention to achieve the object, there is provided a printed circuit board including: a connection pad consisting of a seed layer formed on an upper surface of an insulating layer and a metal layer formed on an upper surface of the seed layer; a first plating layer formed to surround the connection pad; and a second plating layer formed on an upper surface of the first plating layer except a side surface of the first plating layer.

Here, the connection pad may be a connection pad for wire bonding.

Further, the first plating layer may be made of nickel (Ni) or an alloy material containing nickel (Ni).

In addition, the second plating layer may be made of gold (Au) or an alloy material containing gold (Au).

In particular, the first plating layer may be formed on an upper surface of the connection pad thicker than on a side surface of the connection pad.

Further, the first plating layer may be formed to surround a side surface of the seed layer included in the connection pad.

In accordance with another aspect of the present invention to achieve the object, there is provided a method of manufacturing a printed circuit board, which includes the steps of: providing an insulating layer having a seed layer thereon; forming a plating resist, from which a connection pad forming region is selectively removed, on an upper surface of the insulating layer; forming a connection pad in the region from which the plating resist is removed; etching the connection pad selected among the connection pads; forming a first plating layer to surround the etched connection pad; forming a second plating layer on an upper surface of the first plating layer except a side surface of the first plating layer; removing the plating resist; and removing the remaining seed layers except the seed layer having the connection pad thereon.

At this time, in the step of forming the first plating layer to surround the etched connection pad, the first plating layer may be formed on an upper surface of the connection pad thicker than on a side surface of the connection pad.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a cross-sectional view showing a printed circuit board in accordance with an embodiment of the present invention; and

FIGS. 2 to 11 are cross-sectional views showing a process of manufacturing a printed circuit board in accordance with an embodiment of the present invention, wherein

FIG. 2 is a cross-sectional view showing the step of providing an insulating layer having a seed layer thereon,

FIG. 3 is a cross-sectional view showing the step of forming a plating resist, from which a connection pad forming region is selectively removed, on an upper surface of the insulating layer,

FIG. 4 is a cross-sectional view showing the step of forming a connection pad in the region from which the plating resist is removed,

FIG. 5 is a cross-sectional view showing the step of forming an etching resist on upper surfaces of the connection pad and the plating resist,

FIG. 6 is a cross-sectional view showing the step of etching the connection pad selected among the connection pads,

FIG. 7 is a cross-sectional view showing the step of forming a first plating layer to surround the etched connection pad,

FIG. 8 is a cross-sectional view showing the step of forming a second plating layer on an upper surface of the first plating layer except a side surface of the first plating layer,

FIG. 9 is a cross-sectional view showing the step of removing the plating resist,

FIG. 10 is a cross-sectional view showing the step of removing the remaining seed layers except the seed layer having the connection pad, and

FIG. 11 is a cross-sectional view showing the step of forming a solder resist on the insulating layer.

### DETAILED DESCRIPTION OF THE PREFERABLE EMBODIMENTS

Hereinafter, specific embodiments of the present invention will be described with reference to the drawings. The following embodiments merely illustrate the present invention, and the present invention is not limited to the following embodiments.

In describing the present invention, specific descriptions of well-known techniques are omitted so as not to unnecessarily obscure the embodiments of the present invention. The following terms are defined in consideration of functions of the present invention and may be changed according to users or operator's intentions or customs. Thus, the terms shall be defined based on the contents described throughout the specification.

The technical sprit of the present invention should be defined by the attached claims, and the following embodiments are provided as examples to efficiently convey the technical spirit of the invention to those skilled in the art.

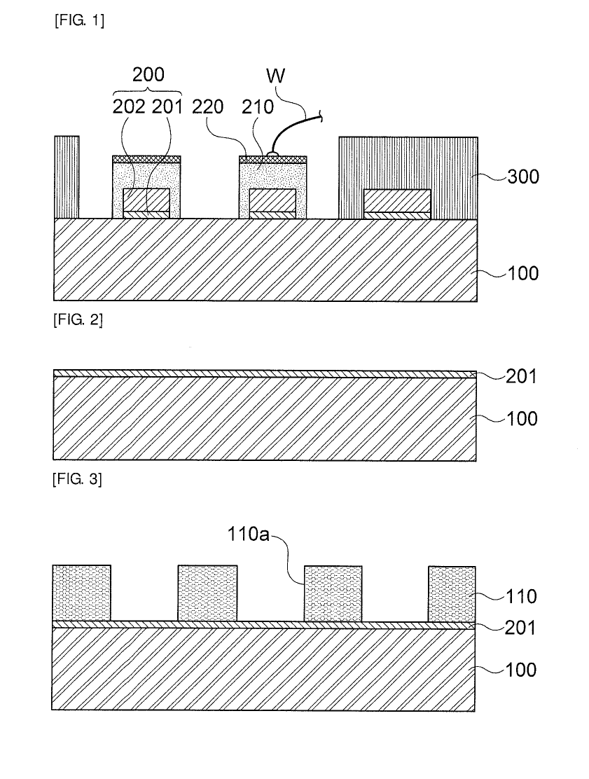

FIG. 1 is a cross-sectional view of a printed circuit board in accordance with an embodiment of the present invention.

As shown in FIG. 1, the printed circuit board according to an embodiment of the present invention may include a connection pad 200, which consists of a seed layer 201 formed on an upper surface of an insulating layer 100 and a metal layer 202 formed on an upper surface of the seed layer 201, a first plating layer 210 formed to surround the connection pad 200, and a second plating layer 220 formed on an upper surface of the first plating layer 210 except a side surface of the first plating layer 210.

The insulating layer 100 may serve as a support for forming a circuit pattern including the connection pad 200 on an upper surface or both surfaces thereof and may be a thermosetting or thermoplastic polymer substrate, a ceramic substrate, an organic-inorganic composite substrate, or a glass fiber impregnated substrate. When the insulating layer 100 contains a polymer resin, the insulating layer 100 may contain an epoxy insulating resin. In contrast, the insulating layer 100 may be made of an insulating material containing a polyimide resin.

A plurality of connection pads 200 may be formed on the upper surface of the insulating layer 100 to be connected to the circuit pattern (not shown in the drawing).

The connection pad 200, which is connected to an electronic component mounted on the printed circuit board, may be a connection pad 200 for wire bonding to be electrically connected to the electronic component through a wire W by wire bonding.

Here, the connection pad 200 may be made of copper (Cu) which is a metal having electrical conductivity.

At this time, the connection pad 200 may include the seed layer 201 formed on the upper surface of the insulating layer 100 and the metal layer 202 formed on the upper surface of the seed layer 201 by a copper plating process.

The first plating layer 210 may be formed on an outer side of the connection pad 200.

Here, the first plating layer 210 may be formed by a nickel (Ni) electroplating method. Further, the first plating layer 210 may be made of only nickel (Ni) or an alloy material of phosphor (P), boron (B), tungsten (W), or cobalt (Co) containing nickel (Ni).

At this time, the first plating layer 210 may be formed to surround the connection pad 200.

In particular, the first plating layer 210 may be formed on the upper surface of the insulating layer 100 to surround all side surfaces of the seed layer 201 and the metal layer 202 and on an upper surface of the metal layer 202 so as to cover the entire surface of the connection pad 200 except the other surface of the connection pad 200 in contact with the insulating layer 100.

In addition, the first plating layer 210 may be formed on an upper surface of the connection pad 200 thicker than on a side surface of the connection pad 200.

That is, the thickness of the first plating layer 210 formed on the upper surface of the connection pad 200 may be larger than the thickness of the first plating layer 210 formed on the side surface of the connection pad 200.

Accordingly, it is possible to absorb shock applied to the connection pad 200 by forming the first plating layer 210 on the upper surface of the connection pad 200 thicker than the first plating layer 210 on the side surface of the connection pad 200 to buffer the shock in a process of bonding the wire W to the connection pad 200 by a mounter which mounts the wire W during wire bonding, thereby protecting the connection pad 200.

Meanwhile, the second plating layer 220 may be formed on the upper surface of the first plating layer 210.

Here, the second plating layer 220, which is provided to increase the adhesion between the wire W and the connection pad 200 during wire bonding and improve electrical connection, may be made of gold (Au) or an alloy material containing gold (Au).

At this time, the second plating layer 220 may be formed to have a very small thickness compared to the thickness of the connection pad 200 and the first plating layer 210.

In particular, the second plating layer 220 is preferred to be formed on the upper surface of the first plating layer 210 except the side surface of the first plating layer 210.

At this time, since the connection pad is a connection pad for wire bonding, the wire W is bonded and connected to an upper surface of the second plating layer 220 through solder. Accordingly, the second plating layer 220 to which the wire W is bonded can be formed only on the upper surface of the first plating layer 210.

Accordingly, it is possible to secure the interval between the adjacent connection pads and miniaturize the connection pad 200 while securing the reliability with the wire W during wire bonding by forming the second plating layer 220 on the upper surface of the first plating layer 210 except the side surface of the first plating layer 210 to reduce the size of the connection pad compared to the width of the conventional connection pad having the first and second plating layers thereon, consequently resulting in the reduction in the size and number of layers of the printed circuit board. Further, it is possible to reduce manufacturing costs by forming the second plating layer 220 on the upper surface of the first plating layer 210.

Meanwhile, a solder resist 300 may be selectively formed on the insulating layer 100 to protect the connection pad 200 and the insulating layer 100 and secure electrical insulation.

A process of manufacturing the printed circuit board according to an embodiment of the present invention configured as above will be described below.

FIGS. 2 to 7 are cross-sectional views showing a process of manufacturing a printed circuit board according to an embodiment of the present invention.

First, as shown in FIG. 2, the step of providing an insulating layer 100 having a seed layer 201 thereon may be performed.

Here, the seed layer 201 may be made of a copper (Cu) material and formed on an upper surface of the insulating layer 100, which is made of an insulating material, by a sputtering or electroless copper plating method.

Next, as shown in FIG. 3, the step of forming a plating resist 110, from which a connection pad forming region is selectively removed, on the upper surface of the insulating layer 110.

Here, the plating resist 110 may be a dry film which is a photosensitive resist.

At this time, the plating resist 110 is a means for preventing the remaining portion except the connection pad forming region from being plated when performing a plating process for forming a metal layer 202 on an upper surface of the seed layer 201.

In addition, the plating resist 110 having a plating opening 110a therein may be formed by a photolithography method, which sequentially performs exposure, development, and etching, after forming the dry film, which is a photosensitive resist, on the upper surface of the insulating layer 100.

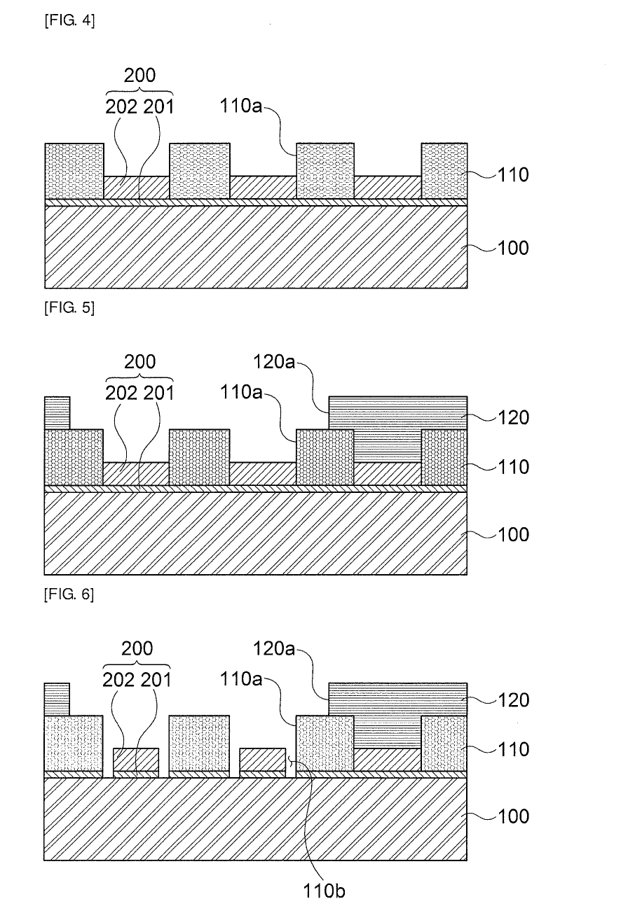

Next, as shown in FIG. 4, a connection pad 200 may be formed by performing a plating process on the plating opening 110a.

Here, the connection pad 200 may be made of the same copper (Cu) material as the seed layer 201, and the connection pad 200 including the seed layer 201 and the metal layer 202 may be formed by forming the metal layer 202 on the plating opening 110a of the plating resist 110 through electroplating.

Next, as shown in FIG. 5, an etching resist 120 may be formed on upper surfaces of the connection pad 200 and the plating resist 110.

Here, an etching opening 120a may be formed in the etching resist 120 to open the selected connection pad 200.

At this time, the etching resist 120 having the etching opening 120a therein may be formed by a photolithography method, which sequentially performs exposure, development, and etching, after forming the dry film, which is a photosensitive resist, on the upper surfaces of the connection pad 200 and the plating resist 110.

After that, as shown in FIG. 6, the step of etching the connection pad 200 selected through the etching opening 120a may be performed.

Here, an outer portion of the connection pad 200 selected through the etching opening 120a may be etched.

At this time, a gap 110b may be formed between the connection pad 200 and the plating resist 110 by performing etching to the seed layer 201 of the connection pad 200 to open a portion of the insulating layer 100 corresponding to the outer portion of the connection pad 200.

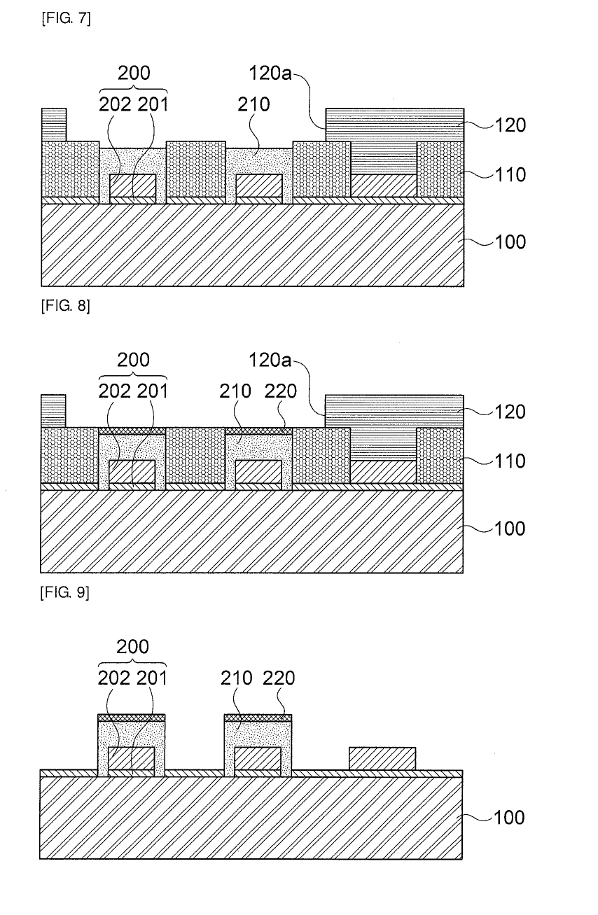

Next, as shown in FIG. 7, the step of forming a first plating layer 210 to surround the etched connection pad 200 may be performed.

Here, the first plating layer 210 may be made of nickel (Ni) or an alloy material containing nickel (Ni) and formed to cover the gap 110b between the connection pad 200 and the plating resist 110 and the upper surface of the connection pad 200 by performing electroplating or electroless plating in a state in which the plating resist 110 is not removed.

At this time, the first plating layer 210 is preferred to be formed on the upper surface of the connection pad 200 thicker than on a side surface of the connection pad 200.

That is, it is possible to absorb shock applied to the connection pad 200 by forming the first plating layer 210 on the upper surface of the connection pad 200 thicker than the first plating layer 210 on the side surface of the connection pad 200 to buffer the shock in a process of bonding a wire W to the connection pad 200 by a mounter which mounts the wire W during wire bonding, thereby effectively protecting the connection pad 200.

Next, as shown in FIG. 8, the step of forming a second plating layer 220 on an upper surface of the first plating layer 210 except a side surface of the first plating layer 210 may be performed.

Here, like the first plating layer 210, the second plating layer 220 may be formed on the upper surface of the first plating layer 210 except the side surface of the first plating layer 210 by performing electroplating or electroless plating in a state in which the plating resist 110 is not removed.

That is, it is possible to reduce the size and number of layers of the printed circuit board by forming the second plating layer 220 on the upper surface of the first plating layer 210 to enable miniaturization compared to the conventional connection pad.

Meanwhile, in the prior art, since the corner of the uppermost portion of the connection pad is rounded after the formation of the plating layer, the wire W is unstably bonded to the round corner during wire bonding, thus frequently causing failures such as non-bonding or separation of the wire W from the connection pad.

However, in the present embodiment, since the plating for forming the second plating layer 220 is performed in a state in which the plating resist 110 is not removed, the corner of the second plating layer 220 laminated on the uppermost portion of the connection pad 200 is formed flat and an upper surface of the second plating layer 220 is formed flat, thus preventing failures such as degradation of bonding strength during wire bonding.

Next, as shown in FIG. 9, the step of removing the plating resist 110 may be performed.

At this time, the plating resist 110 may be removed with the etching resist 120.

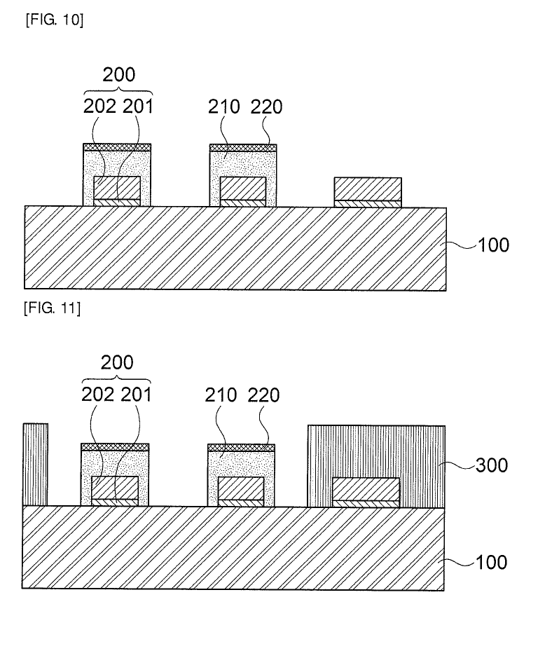

Next, as shown in FIG. 10, the step of removing the remaining seed layers 201 except the seed layer 201 having the connection pad 200 may be performed.

At this time, since the first plating layer 210 is formed to surround the connection pad 200 to prevent the connection pad 200 from being etched during the etching process of removing the seed layer 201, an undercut between the connection pad 200 and the insulating layer 100 due to excessive etching is prevented to improve the reliability between the connection pad 200 and the insulating layer 100.

After that, as shown in FIG. 11, a solder resist 300 may be selectively formed on the insulating layer 100 to protect the connection pad 200 and the insulating layer 100 and secure electrical insulation.

As described above, the printed circuit board and the method of manufacturing the same according to an embodiment of the present invention can reduce manufacturing costs and form the connection pad minutely while securing the reliability with the wire during wire bonding by forming the first plating layer to surround the connection pad and forming the second plating layer only on the upper surface of the first plating layer except the side surface of the first plating layer. Accordingly, the size and number of layers of the printed circuit board can be reduced.

Further, the first plating layer is formed to surround the connection pad including the seed layer to prevent the undercut between the connection pad and the insulating layer due to the excessive etching of the connection pad, thus improving the reliability between the connection pad and the insulating layer.

In addition, the occurrence of failures such as contact failure of the wire and damage to the connection pad can be prevented by absorbing shock in the process of closely bonding the wire to the connection pad by the mounter during wire bonding while securing the interval between the adjacent connection pads.

Although the present invention has been described in detail with reference to the preferable embodiments, it will be appreciated by those skilled in the art that various modifications may be made in these embodiments without departing from the scope of the present invention.

Therefore, the scope of the present invention should not be limited by the described embodiments but defined by the appended claims and their equivalents.

What is claimed is:

1. A printed circuit board comprising:
a connection pad consisting of a seed layer formed on an upper surface of an insulating layer and a metal layer formed on an upper surface of the seed layer;
a first plating layer formed to surround the connection pad; and
a second plating layer formed on an upper surface of the first plating layer except a side surface of the first plating layer.

2. The printed circuit board according to claim 1, wherein the connection pad is a connection pad for wire bonding.

3. The printed circuit board according to claim 1, wherein the first plating layer is made of nickel (Ni) or an alloy material containing nickel (Ni).

4. The printed circuit board according to claim 1, wherein the second plating layer is made of gold (Au) or an alloy material containing gold (Au).

5. The printed circuit board according to claim 1, wherein the first plating layer is formed on an upper surface of the connection pad thicker than on a side surface of the connection pad.

6. The printed circuit board according to claim 1, wherein the first plating layer is formed to surround a side surface of the seed layer included in the connection pad.

7. A method of manufacturing a printed circuit board, comprising:
providing an insulating layer having a seed layer thereon;
forming a plating resist, from which a connection pad forming region is selectively removed, on an upper surface of the insulating layer;
forming a connection pad in the region from which the plating resist is removed;
etching the connection pad selected among the connection pads;
forming a first plating layer to surround the etched connection pad;
forming a second plating layer on an upper surface of the first plating layer except a side surface of the first plating layer;
removing the plating resist; and
removing the remaining seed layers except the seed layer having the connection pad thereon.

8. The method of manufacturing a printed circuit board according to claim 1, wherein in forming the first plating layer to surround the etched connection pad, the first plating layer is formed on an upper surface of the connection pad thicker than on a side surface of the connection pad.
